(19) United States
(12) Patent Application Publication
(10) Pub. No.: US 2025/0079988 A1
(43) Pub. Date: Mar. 6, 2025

(54) DC/DC PARTIAL POWER CONVERTER BASED ON PCB EMBEDDING TECHNOLOGY

(71) Applicant: Huawei Digital Power Technologies Co., Ltd., Shenzhen (CN)

(72) Inventors: Piniwan Thiwanka Bandara Wijekoon, Nuremberg (DE); Lasse Petteri Palm, Nuremberg (DE)

(73) Assignee: Huawei Digital Power Technologies Co., Ltd., Shenzhen (CN)

(21) Appl. No.: 18/951,465

(22) Filed: Nov. 18, 2024

Related U.S. Application Data
(63) Continuation of application No. PCT/EP2022/063505, filed on May 19, 2022.

(51) Int. Cl. H02M 3/158; H02J 3/38; H02M 1/00; H02M 3/00; H05K 1/18

(52) U.S. Cl. CPC H02M 3/158; H02J 3/38; H02M 1/0083; H02M 3/003; H05K 1/181; H02J 2300/26

(57) ABSTRACT

Disclosed is a DC/DC partial power converter (PPC), comprising a plurality of first switching cells; a capacitive energy storage element; a plurality of second switching cells; and a printed circuit board (PCB). A power input terminal of the respective first switching cell is connectable to a respective DC power source. Power output terminals of the respective first switching cell and power input terminals of the respective second switching cell are connected in parallel to the capacitive energy storage element. A power output terminal of the respective second switching cell is connectable to a DC power output bus. The respective first or second switching cell comprises at least one die package being embedded in the PCB. Electrical terminals of the respective at least one embedded die package are connected with corresponding electrical terminals on the PCB. This improves a power density and cost of DC/DC partial power converters.

### CROSS-REFERENCE TO RELATED APPLICATIONS

This application is a continuation of International Application No. PCT/EP2022/063505, filed on May 19, 2022, the disclosure of which is hereby incorporated by reference in its entirety.

### TECHNICAL FIELD

The present disclosure relates generally to the field of electrical power conversion, and more particularly to a direct current-to-direct current (DC/DC) partial power converter.

### BACKGROUND ART

Photovoltaic (PV) modules generate variable electrical DC power in accordance with an angle of incidence and an intensity of the solar radiation, among other factors.

A power transfer from the variable power source to a load may be maximized by adjusting an electrical characteristic of the load as conditions vary. This is known as maximum power point tracking (MPPT). In the case of DC source feeding a DC load MPPT represents one particular form of DC/DC power conversion.

DC/DC power conversion may involve full power processing or partial/fractional power processing.

Full power processing deals with a total power of the system, and either requires full voltage and current rated semiconductor devices or multiple low-voltage semiconductor devices in series/parallel to form the converter circuitry, which raises reliability, cost, electrical loss, size, and weight issues. A typical semiconductor packaging for solder-less mounting on a full power converter's printed circuit board (PCB) uses one flat face for electrical interconnection and another flat face for thermal dissipation.

Partial or fractional power processing merely handles a portion of the total power of the system at all input variations, and therefore requires low-voltage and/or low-current semiconductor devices only. This may already alleviate the afore-mentioned issues of full power processing, but there is still room for improvement due to lower electrical loss and higher efficiency of the semiconductor devices.

### SUMMARY

It is thus an object to further improve a power density and cost of DC/DC partial power converters.

The foregoing and other objects are achieved by the features of the independent claims. Further implementation forms are apparent from the dependent claims, the description, and the figures.

According to an aspect, a DC/DC partial power converter (PPC) is provided, comprising a plurality of first switching cells; a capacitive energy storage element; a plurality of second switching cells; and a printed circuit board, PCB. A power input terminal of the respective first switching cell is connectable to a respective DC power source. Power output terminals of the respective first switching cell and power input terminals of the respective second switching cell are connected in parallel to the capacitive energy storage element. A power output terminal of the respective second switching cell is connectable to a DC power output bus. The respective first or second switching cell comprises at least one die package being embedded in the PCB. Electrical terminals of the respective at least one embedded die package are connected with corresponding electrical terminals on the PCB.

Low voltage insulation requirement (i.e., <200V), low electrical loss and high efficiency of the semiconductor devices deployed in partial power converters enables the use of PCB embedded technology and PCB-based cooling instead of possible manual solder, bulky components, big heatsinks and thermal design. As used herein, PCB embedding may refer to embedding of electronic components such as pre-packaged semiconductor chips, i.e., die packages, into a PCB, and optimization of their three-dimensional electrical interconnection. A potential high-frequency switching operation allows for a compact device and cell level optimizations. This yields a highly compact system based on a single PCB with highly optimized pre-packaged cells embedded, which improves a power density and cost with regard to known PPCs. The system is simple to scale to high numbers of PV strings such as 32 strings or higher. In addition, integration of control and driving circuits in close proximity to the switching power cells minimizes latencies in the control loop, thereby improving a closed-loop control response, making a power tracking capability more precise, and removing oscillation in the PV string. Overall, embedding pre-packaged PPCs facilitates high-power application such as 1500V/320 kW+ and automated mass manufacturing, thereby further improving a cost of DC/DC PPCs.

In a possible implementation form, the respective first or second switching cell may comprise a series connection of solid-state cell switches.

In a possible implementation form, the respective first or second switching cell may comprise a cell inductor being connected at one end thereof to a common terminal of the series connection of the solid-state cell switches.

In a possible implementation form, the respective first or second switching cell may comprise a cell capacitor being connected in parallel to the series connection of the solid-state cell switches.

In a possible implementation form, the respective first or second switching cell may comprise one of: a 2-level (2L) switching cell; a 3-level neutral point clamped (3L-NPC), switching cell; and a 3-level flying capacitor (3L-FC) switching cell or any other multi-level switching cell.

The 2L switching cell combines a low quantity of output voltage levels and reasonable Total Harmonic Distortion (THD) performance. The 3L-NPC and 3L-FC switching cell can synthesize more output voltage levels, thereby improving a THD performance with regard to the 2L switching cell. Furthermore, in multi-level cells as compared to 2L, voltage and thermal stress are distributed among multiple devices and therefore, can simplify the design.

In a possible implementation form, the at least one die package may comprise a single-switch die.

The single-switch die package can include a high-side switch or a low-side switch of a half bridge. A connection between the high-side and a low-side switch dies to form the half bridge may be realized on PCB level after the dies are embedded inside the PCB. Thereby, a power density and cost of DC/DC PPCs is improved.

In a possible implementation form, the at least one die package may comprise a multi-switch dic.

The multi-switch die package is very simple and even standard surface-mount device (SMD) packages can be used. To achieve the best performance and usability the package can be optimized for embedding purposes. The multi-switch die package can include the half-bridge, which makes the embedding easier and lower cost and it also offer the best electrical performance. In such a half bridge package the parasitic of the low-side and high-side switches, such as MOSFETS, can be minimized, and a power density and cost of DC/DC PPCs may be improved even further with regard to single-switch dies.

In a possible implementation form, the multi-switch die may comprise the series connection of the solid-state cell switches.

In a possible implementation form, the electrical terminals of the respective at least one embedded die package may be exposed on a flat face of the same, and may further be connected with the corresponding electrical terminals on a flat face of the PCB corresponding in face orientation.

Thereby, die packages with single-sided connections may be embedded into the PCB.

In a possible implementation form, the electrical terminals of the respective at least one embedded die package may be exposed on respective flat faces of the same, and may further be connected with the corresponding electrical terminals on respective flat faces of the PCB corresponding in face orientation.

Thereby, die packages with double-sided connections may be embedded into the PCB. The double-sided connections are preferred as this allows for real 3D assembly, that is, to connect and route the connection to the common/half bridge terminal (providing a half-bridge voltage V_{SWH}) of the series connection of the solid-state cell switches on one side (i.e., flat face) of the PCB and the other connections to the input and ground terminals (receiving the input voltage V_{IN} relative to the ground potential P_{GND}) as well as the gate terminals on the other side of the PCB, to place the electrical components in more ideal locations, to minimize the distances between the components and thus to reduce parasitics.

In a possible implementation form, the cell inductor of the respective at least one embedded die package may be mounted on a first one of the flat faces of the PCB.

The inductor can be mounted directly on top of the common terminal V_{SWH}, thereby minimizing the connection lengths.

In a possible implementation form, the cell capacitor of the respective at least one embedded die package may be mounted on a second one of the flat faces of the PCB different from the first one.

One or more capacitors, including the cell capacitor, can be mounted on an ideal location and directly on top of the connections of the respective package, thereby minimizing the connection lengths either.

In a possible implementation form, the multi-switch die may comprise the cell capacitor.

The cell capacitor can even be integrated into the respective die package, thereby further improving a power density and cost of DC/DC PPCs.

In a possible implementation form, the capacitive energy storage element may comprise a buffer capacitor.

In a possible implementation form, the respective DC power source may comprise a series connection of photovoltaic (PV) modules.

In a possible implementation form, the PPC may comprise a maximum power point tracker, MPPT.

### BRIEF DESCRIPTION OF DRAWINGS

The above-described aspects and implementations will now be explained with reference to the accompanying drawings, in which the same or similar reference numerals designate the same or similar elements.

The drawings are to be regarded as being schematic representations, and elements illustrated in the drawings are not necessarily shown to scale. Rather, the various elements are represented such that their function and general purpose become apparent to those skilled in the art.

FIG. 1 illustrates a DC/DC partial power converter in accordance with the present disclosure;

FIG. 2 illustrates an exemplary PCB of the DC/DC PPC in accordance with the present disclosure;

FIGS. 3A-3C illustrate an exemplary first or second switching cell comprising single-switch die packages for PCB embedding in accordance with the present disclosure;

FIGS. 4A-4B illustrate single-sided and double-sided connections, respectively, for PCB embedding of single-switch die packages 17;

FIGS. 5A-5C illustrate an exemplary first or second switching cell comprising a multi-switch die package for PCB embedding in accordance with the present disclosure;

FIGS. 6A-6B illustrate an exemplary first or second switching cell comprising a multi-switch die package with integrated cell capacitor for PCB embedding in accordance with the present disclosure;

FIGS. 7A-7C illustrate single-sided and double-sided connections, respectively, for PCB embedding of multi-switch die packages including cell capacitors; and

FIG. 8 illustrates an exemplary mounting of cell inductor and cell capacitor on a PCB-embedded multi-switch die package having double-sided connections.

### DETAILED DESCRIPTIONS OF DRAWINGS

In the following description, reference is made to the accompanying drawings, which form part of the disclosure, and which show, by way of illustration, specific aspects of embodiments of the present disclosure or specific aspects in which embodiments of the present disclosure may be used. It is understood that embodiments of the present disclosure may be used in other aspects and comprise structural or logical changes not depicted in the figures. The following detailed description, therefore, is not to be taken in a limiting sense, and the scope of the present disclosure is defined by the appended claims.

For instance, it is understood that a disclosure in connection with a described method may also hold true for a corresponding apparatus or system configured to perform the method and vice versa. For example, if one or a plurality of specific method steps are described, a corresponding device may include one or a plurality of units, e.g. functional units, to perform the described one or plurality of method steps (e.g. one unit performing the one or plurality of steps, or a plurality of units each performing one or more of the plurality of steps), even if such one or more units are not explicitly described or illustrated in the figures. On the other hand, for example, if a specific apparatus is described based on one or a plurality of units, e.g. functional units, a corresponding method may include one step to perform the functionality of the one or plurality of units (e.g. one step performing the functionality of the one or plurality of units, or a plurality of steps each performing the functionality of one or more of the plurality of units), even if such one or plurality of steps are not explicitly described or illustrated in the figures. Further, it is understood that the features of the various exemplary embodiments and/or aspects described herein may be combined with each other, unless specifically noted otherwise.

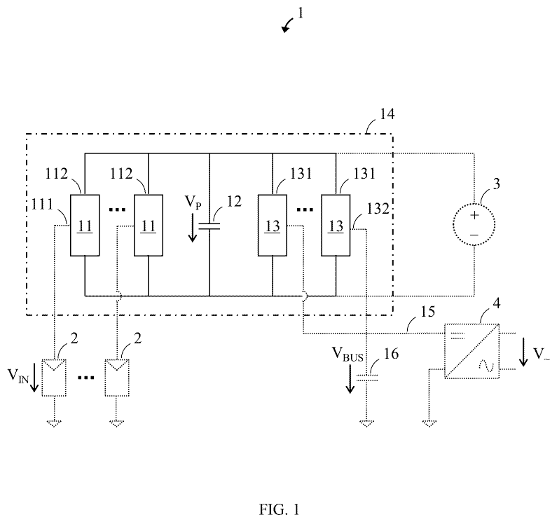

FIG. 1 illustrates a DC/DC partial power converter 1 in accordance with the present disclosure.

The PPC 1 comprises a plurality of first switching cells 11 and a plurality of second switching cells 13.

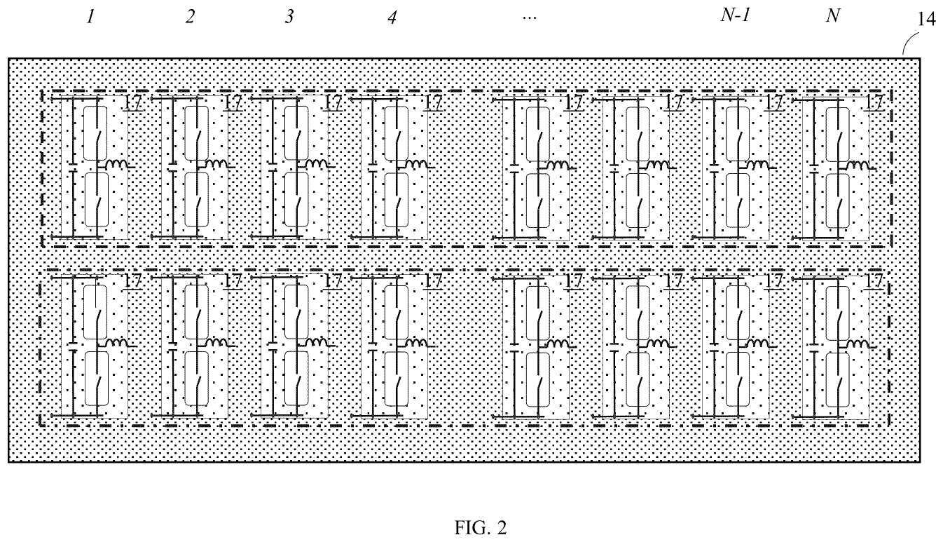

The respective first or second switching cell 11, 13 may comprise a series connection of solid-state cell switches 171, 172 (not shown, see FIG. 2) known as a half bridge. The solid-state cell switches 171, 172 may respectively comprise MOSFET switches, for example.

A power input terminal 111 of the respective first switching cell 11 is connectable to a respective DC power source 2, such as a series connection (i.e., string) of photovoltaic (PV) modules generating a time-variant DC string voltage V_{IN}. The respective first switching cell 11 may therefore be termed “PV-side leg” of the PPC 1 as well.

The PPC 1 further comprises a capacitive energy storage element 12, such as a buffer capacitor, establishing and providing a voltage V_{P}.

Power output terminals 112 of the respective first switching cell 11 and power input terminals 131 of the respective second switching cell 13 are connected in parallel to the capacitive energy storage element 12. Additionally, an indirect DC voltage source 3, such as a dual active bridge (DAB) converter or a series resonant converter, may be connected in parallel to the capacitive energy storage element 12 as well.

A power output terminal 132 of the respective second switching cell 13 is connectable to a DC power output bus 15. As such, the respective second switching cell 13 may also be called “bus-side leg” of the PPC 1. An output capacitor 16 may be used to establish and provide a constant DC voltage VBUS.

The PPC 1 further comprises a printed circuit board, PCB 14. The respective first or second switching cell 11, 13 comprises at least one die package 17 being embedded in the PCB 14.

In view of the time-variant DC input voltage V_{IN} and the constant DC output voltage VBUS, the PPC 1 may particularly comprise a maximum power point tracker (MPPT) so as to maximize a power transfer from the variable power source to the load (e.g., power grid) as conditions vary.

In case of an AC load, such as an AC power grid, the constant DC output voltage VBUS may feed an inverter 4 being designed to supply the load with AC power.

FIG. 2 illustrates an exemplary PCB 14 of the DC/DC PPC 1 in accordance with the present disclosure.

The PCB 14 may comprise one or more cores being made of glass-reinforced epoxy laminate material “(FR4”) for its properties as an electrical insulator in both dry and humid conditions possessing considerable mechanical strength. The PCB 14 may further comprise two (“dual-layer”) or more (“multi-layer”) layers of routed waveguides, such as metallic/copper traces.

The PCB 14 of FIG. 2 comprises a plurality of die packages 17 organized as a N×2 matrix. Without loss of generality, the respective die package 17 of FIG. 2 comprises a multi-switch die package 17. In other words, there is a one-on-one correspondence between the respective die package 17 and the respective first or second switching cell 11, 13.

The respective first or second switching cell 11, 13 may comprise a cell topology of a 2-level (2L) switching cell, a 3-level neutral point clamped (3L-NPC) switching cell, and a 3-level flying capacitor (3L-FC) switching cell. Without loss of generality, the respective first or second switching cell 11, 13 of FIG. 2 comprises a 2L switching cell topology.

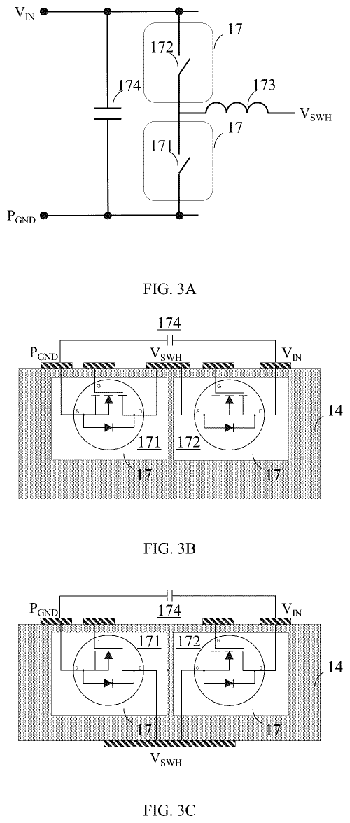

FIGS. 3A-3C illustrate an exemplary first or second switching cell 11, 13 comprising single-switch die packages 17 for PCB embedding in accordance with the present disclosure.

Without loss of generality, the exemplary first or second switching cell 11, 13 shown in FIG. 3A comprises a 2L switching cell topology, including two single-switch die packages 17 forming a series connection of solid-state cell switches 171, 172 known as half bridge.

If the respective dies relating to low-side and high-side solid-state cell switches 171, 172 are packaged separately, the packaging becomes simple. More specifically, a standard package can be used, but with an optimized package a performance may be improved.

The respective first or second switching cell 11, 13 may further comprise a cell inductor 173 being connected at one (first) end thereof to a common/half bridge terminal of the series connection of the solid-state cell switches 171, 172, and may further comprise a cell capacitor 174 being connected in parallel to the series connection of the solid-state cell switches 171, 172.

In operation, an input voltage V_{IN} with respect to the ground potential P_{GND} may be applied to the parallel connection of the cell capacitor 174 and the half bridge 171, 172, and a half bridge voltage V_{SWH} may be obtained at another (second) end of the cell inductor 173.

Electrical terminals of the respective at least one embedded die package 17 are connected with corresponding electrical terminals on the PCB 14, as shown in FIGS. 3B-3C below.

According to FIG. 3B, the electrical terminals of the respective at least one embedded die package 17 may be exposed on a flat face of the same, and may further be connected with the corresponding electrical terminals on a flat face of the PCB 14 corresponding in face orientation. In other words, the example of FIG. 3B illustrates single-sided connections, wherein the input terminal, the ground terminal, the common/half bridge terminal as well as the gate terminals are all directed to a “top” face/side of the PCB 14.

According to FIG. 3C, the electrical terminals of the respective at least one embedded die package 17 may be exposed on respective flat faces of the same, and may further be connected with the corresponding electrical terminals on respective flat faces of the PCB 14 corresponding in face orientation. That is to say, the example of FIG. 3C illustrates double-sided connections, wherein the input terminal, the ground terminal and the gate terminals are directed to the “top” face/side of the PCB 14 and the common/half bridge terminal is directed to a “bottom” face/side of the PCB 14.

In accordance with both FIGS. 3B and 3C, the high-side switch 172 and the low-side switch 171 form the half bridge 171, 172 by interconnection on PCB level after their die packages 17 have been embedded inside the PCB 14.

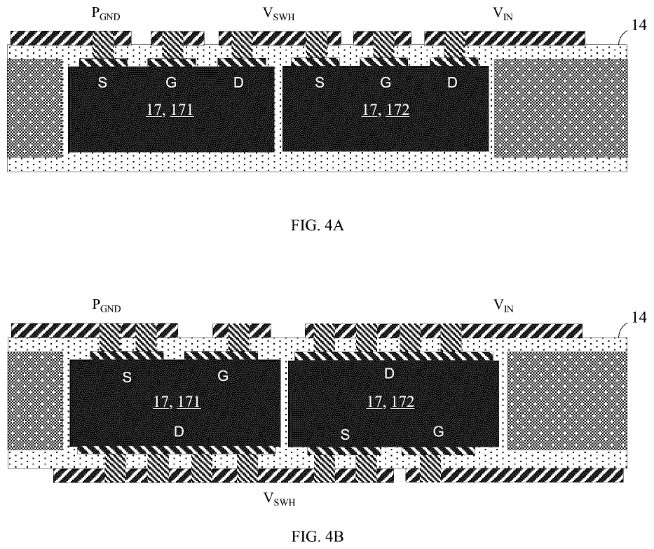

FIGS. 4A-4B illustrate single-sided and double-sided connections, respectively, for PCB embedding of single-switch die packages 17.

According to FIG. 4A, the electrical terminals of the respective at least one embedded die package 17 may be exposed on a flat face of the same, and may further be connected with the corresponding electrical terminals on a flat face of the PCB 14 corresponding in face orientation. In other words, the example of FIG. 4A illustrates single-sided connections, wherein the input terminal, the ground terminal, the common/half bridge terminal as well as the gate terminals are all directed to the “top” face/side of the PCB 14. The connections between the embedded die packages 17 and the PCB 14 will be done with plated copper (Cu) vias. This means that the connections and first layer routings are done on a same side of the PCB 14, if die packages 17 with single-sided connections are used.

According to FIG. 4B, the electrical terminals of the respective at least one embedded die package 17 may be exposed on respective flat faces of the same, and may further be connected with the corresponding electrical terminals on respective flat faces of the PCB 14 corresponding in face orientation. That is to say, the example of FIG. 4B illustrates double-sided connections, wherein the input terminal, the ground terminal and the gate terminals are directed to the “top” face/side of the PCB 14 and the common/half bridge terminal is directed to the “bottom” face/side of the PCB 14. This means that the routing can be divided into two layers, if die packages 17 with double sided connections are used. In connection with double-sided connections, the respective die packages 17 relating to the low-side and high-side solid-state cell switches 171, 172 face different directions. In other terms, one of the respective die packages 17 is flipped with respect to the other. The flipping is done during the embedding.

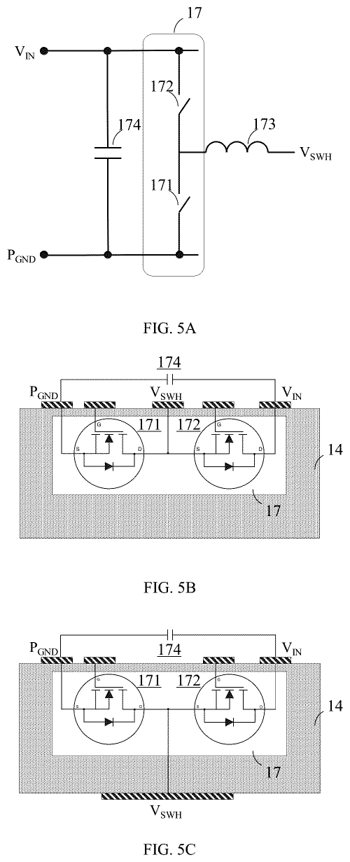

FIGS. 5A-5C illustrate an exemplary first or second switching cell 11, 13 comprising a multi-switch die package 17 for PCB embedding in accordance with the present disclosure.

Without loss of generality, the exemplary first or second switching cell 11, 13 shown in FIG. 5A comprises a 2L switching cell topology, including a multi-switch die package 17 comprising a series connection of solid-state cell switches 171, 172 known as half bridge.

The respective first or second switching cell 11, 13 may further comprise a cell inductor 173 being connected at one (first) end thereof to a common/half bridge terminal of the series connection of the solid-state cell switches 171, 172, and may further comprise a cell capacitor 174 being connected in parallel to the series connection of the solid-state cell switches 171, 172.

In operation, an input voltage V_{IN} with respect to the ground potential P_{GND} may be applied to the parallel connection of the cell capacitor 174 and the half bridge 171, 172, and a half bridge voltage V_{SWH} may be obtained at another (second) end of the cell inductor 173.

Electrical terminals of the respective at least one embedded die package 17 are connected with corresponding electrical terminals on the PCB 14, as shown in FIGS. 5B-5C below.

According to FIG. 5B, the electrical terminals of the respective at least one embedded die package 17 may be exposed on a flat face of the same, and may further be connected with the corresponding electrical terminals on a flat face of the PCB 14 corresponding in face orientation. In other words, the example of FIG. 5B illustrates single-sided connections, wherein the input terminal, the ground terminal, the common/half bridge terminal as well as the gate terminals are all directed to the “top” face/side of the PCB 14.

According to FIG. 5C, the electrical terminals of the respective at least one embedded die package 17 may be exposed on respective flat faces of the same, and may further be connected with the corresponding electrical terminals on respective flat faces of the PCB 14 corresponding in face orientation. That is to say, the example of FIG. 5C illustrates double-sided connections, wherein the input terminal, the ground terminal and the gate terminals are directed to the “top” face/side of the PCB 14 and the common/half bridge terminal is directed to the “bottom” face/side of the PCB 14.

In accordance with both FIGS. 5B and 5C, the high-side switch 172 and the low-side switch 171 form the half bridge 171, 172 on package level.

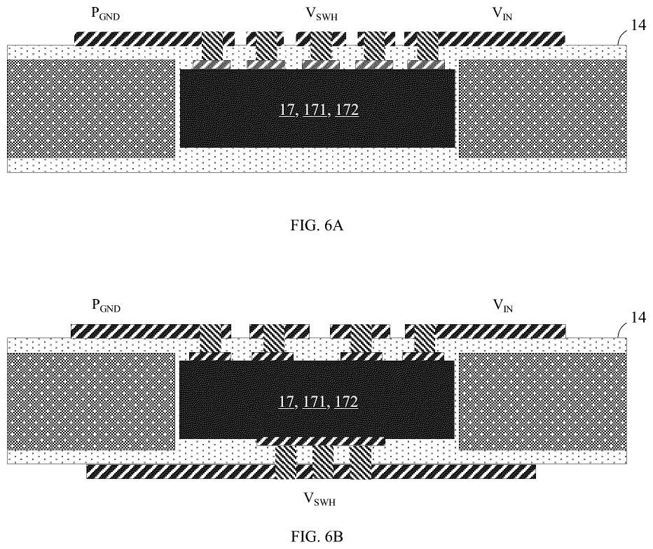

FIGS. 6A-6B illustrate an exemplary first or second switching cell 11, 13 comprising a multi-switch die package 17 with integrated cell capacitor 174 for PCB embedding in accordance with the present disclosure.

According to FIG. 6A, the electrical terminals of the respective at least one embedded die package 17 may be exposed on a flat face of the same, and may further be connected with the corresponding electrical terminals on a flat face of the PCB 14 corresponding in face orientation. In other words, the example of FIG. 6A illustrates single-sided connections, wherein the input terminal, the ground terminal, the common/half bridge terminal as well as the gate terminals are all directed to the “top” face/side of the PCB 14.

According to FIG. 6B, the electrical terminals of the respective at least one embedded die package 17 may be exposed on respective flat faces of the same, and may further be connected with the corresponding electrical terminals on respective flat faces of the PCB 14 corresponding in face orientation. That is to say, the example of FIG. 6B illustrates double-sided connections, wherein the input terminal, the ground terminal and the gate terminals are directed to the “top” face/side of the PCB 14 and the common/half bridge terminal is directed to the “bottom” face/side of the PCB 14.

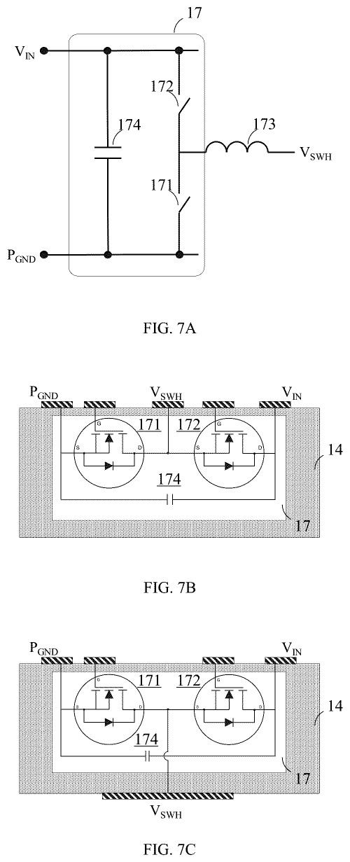

FIGS. 7A-7C illustrate single-sided and double-sided connections, respectively, for PCB embedding of multi-switch die packages 17 including cell capacitors 174.

Without loss of generality, the exemplary first or second switching cell 11, 13 shown in FIG. 7A comprises a 2L switching cell topology, including a multi-switch die package 17 comprising a series connection of solid-state cell switches 171, 172 known as half bridge.

The examples of FIG. 7A-7C differ from those of FIGS. 5A-5C in that the respective embedded (multi) die package 17 can also include additional passive components.

For example, the respective embedded die package 17 (i.e., the respective first or second switching cell 11, 13) may further comprise the cell capacitor 174 being connected in parallel to the series connection of the half bridge 171, 172.

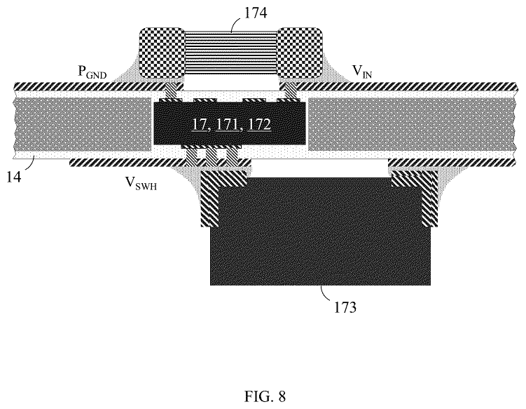

FIG. 8 illustrates an exemplary mounting of cell inductor 173 and cell capacitor 174 on a PCB-embedded multi-switch die package 17 having double-sided connections.

Starting from the example of FIG. 6B, the cell inductor 173 of the respective at least one embedded die package 17 may be mounted on a first one of the flat faces, i.e., the “bottom” face/side of the PCB 14.

The cell capacitor 174 of the respective at least one embedded die package 17 may be mounted on a second one of the flat faces, i.e., the “top” face/side of the PCB 14 different from the first one.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation. A computer program may be stored/distributed on a suitable medium, such as an optical storage medium or a solid-state medium supplied together with or as part of other hardware, but may also be distributed in other forms, such as via the Internet or other wired or wireless telecommunication systems.

What is claimed is:

1. A DC/DC partial power converter, PPC (1), comprising
a plurality of first switching cells (11);
a capacitive energy storage element (12);
a plurality of second switching cells (13); and
a printed circuit board, PCB (14);
a power input terminal (111) of the respective first switching cell (11) being connectable to a respective DC power source (2);
power output terminals (112) of the respective first switching cell (11) and power input terminals (131) of the respective second switching cell (13) being connected in parallel to the capacitive energy storage element (12);
a power output terminal (132) of the respective second switching cell (13) being connectable to a DC power output bus (15);
the respective first or second switching cell (11, 13) comprising at least one die package (17) being embedded in the PCB (14); and
electrical terminals of the respective at least one embedded die package (17) being connected with corresponding electrical terminals on the PCB (14).

2. The PPC (1) of claim 1, wherein the respective first or second switching cell (11, 13) comprising a series connection of solid-state cell switches (171, 172).

3. The PPC (1) of claim 2, wherein the respective first or second switching cell (11, 13) comprising a cell inductor (173) being connected at one end thereof to a common terminal of the series connection of the solid-state cell switches (171, 172).

4. The PPC (1) of claim 2, wherein the respective first or second switching cell (11, 13) comprising a cell capacitor (174) being connected in parallel to the series connection of the solid-state cell switches (171, 172).

5. The PPC (1) of the preceding claim 1, wherein the respective first or second switching cell (11, 13) comprising one of:
a 2-level, 2L, switching cell;
a 3-level neutral point clamped, 3L-NPC, switching cell; and
a 3-level flying capacitor, 3L-FC, switching cell.

6. The PPC (1) of the claim 1, wherein the at least one die package (17) comprising a single-switch die.

7. The PPC (1) of the claim 1, wherein the at least one die package (17) comprising a multi-switch die.

8. The PPC (1) of claim 7, wherein the multi-switch die comprising the series connection of the solid-state cell switches (171, 172).

9. The PPC (1) of claim 1, wherein the electrical terminals of the respective at least one embedded die package (17) being exposed on a flat face of the same, and further being connected with the corresponding electrical terminals on a flat face of the PCB (14) corresponding in face orientation.

10. The PPC (1) of claim 1, wherein the electrical terminals of the respective at least one embedded die package (17) being exposed on respective flat faces of the same, and further being connected with the corresponding electrical terminals on respective flat faces of the PCB (14) corresponding in face orientation.

11. The PPC (1) of claim 1, wherein the cell inductor (173) of the respective at least one embedded die package (17) being mounted on a first one of the flat faces of the PCB (14).

12. The PPC (1) of claim 11, wherein the cell capacitor (174) of the respective at least one embedded die package (17) being mounted on a second one of the flat faces of the PCB (14) different from the first one.

13. The PPC (1) of claim 1, wherein the multi-switch die comprising the cell capacitor (174).

14. The PPC (1) of claim 1, wherein the capacitive energy storage element (12) comprising a buffer capacitor.

15. The PPC (1) of claim 1, wherein the respective DC power source (2) comprising a series connection of photovoltaic, PV, modules.

16. The PPC (1) of claim 15, wherein the PPC (1) comprising a maximum power point tracker, MPPT.
